(19) United States
(12) Patent Application Publication
(10) Pub. No.: US 2025/0380406 A1
(43) Pub. Date: Dec. 11, 2025

(54) VERTICAL BANK REDUNDANCY IN THREE-DIMENSIONAL STACKED DYNAMIC RANDOM-ACCESS MEMORY (DRAM) FOR IMPROVED YIELD

(71) Applicant: QUALCOMM Incorporated, San Diego, CA (US)

(72) Inventors: Mustafa BADAROGLU, San Diego, CA (US); Zhongze WANG, San Diego, CA (US); Woo Tag KANG, San Diego, CA (US); Jihong CHOI, San Diego, CA (US); Hyun LEE, San Diego, CA (US); Giridhar NALLAPATI, San Diego, CA (US); Periannan CHIDAMBARAM, San Diego, CA (US)

(21) Appl. No.: 18/907,383

(22) Filed: Oct. 4, 2024

Related U.S. Application Data
(60) Provisional application No. 63/657,051, filed on Jun. 6, 2024.

(51) Int. Cl. H10B 12/00; H01L 23/538

(52) U.S. Cl. CPC H10B 12/48; H01L 23/5384; H10B 12/50

(57) ABSTRACT

A three-dimensional (3D) stacked memory package is described. The 3D stacked memory package includes a base die, including a repair circuit. The 3D stacked memory package also includes memory dies stacked on the base die. The 3D stacked memory package further includes a package substrate supporting the base die. The 3D stacked memory package also includes data through silicon vias (TSVs) extending between the plurality of memory dies and landing on the base die. The data TSVs are shared on data (DQ) lines for each of the memory dies. Additionally, the repair circuit is configured to remap addresses of failed banks and/or pages across at least two different memory dies of the plurality of memory dies.

### CROSS-REFERENCE TO RELATED APPLICATION

The present application claims the benefit of U.S. Provisional Patent Application No. 63/657,051, filed Jun. 6, 2024, and titled “VERTICAL BANK REDUNDANCY IN THREE-DIMENSIONAL STACKED DYNAMIC RANDOM-ACCESS MEMORY (DRAM) FOR IMPROVED YIELD,” the disclosure of which is expressly incorporated by reference in its entirety.

### BACKGROUND

### Field

Aspects of the present disclosure relate to semiconductor devices and, more particularly, to vertical bank redundancy in three-dimensional (3D) stacked dynamic random-access memory (DRAM) for improved yield.

### Background

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a higher-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D)-stacked memories composed of high-bandwidth memory (HBM) DRAM provide advantages in performance and power for memory-demanding workloads. Single stacked DRAM yield is a significant factor in these 3D stacked memories. For example, a single DRAM yield of 97% is reduced to a stacked yield of less than 78% in an integration scheme that utilizes low-cost wafer-to-wafer stacking of eight wafers. Due to this limited yield, DRAM vendors prefer slow and costly die-to-die stacking for implementing high-bandwidth memory (HBM) solutions. Additionally, conventional repair techniques (e.g., redundant row, column, and error correction code (ECC)) fail to increase the single DRAM wafer yield to a desired level. Utilizing bank-level redundancy in 3D stacked memories is not practical due to a large area penalty because bank-level redundancy specifies redundant bank columns in each channel.

### SUMMARY

A three-dimensional (3D) stacked memory package is described. The 3D stacked memory package includes a base die, including a repair circuit. The 3D stacked memory package also includes memory dies stacked on the base die. The 3D stacked memory package further includes a package substrate supporting the base die. The 3D stacked memory package also includes data through silicon vias (TSVs) extending between the plurality of memory dies and landing on the base die. The data TSVs are shared on data (DQ) lines for each of the memory dies. Additionally, the repair circuit is configured to remap addresses of failed banks and/or pages across at least two different memory dies of the plurality of memory dies.

A method for three-dimensional (3D) stacked dynamic random-access memory (DRAM) repair is described. The method includes configuring a plurality of memory dies of the 3D stacked DRAM to provide vertical bank redundancy of stored data across at least two different memory dies of the plurality of memory dies of the 3D stacked DRAM. The method also includes detecting a failed bank in a first memory die of the plurality of memory dies of the 3D stacked DRAM. The method further includes remapping an address of the failed bank in the first memory die with a redundant bank in a second memory die corresponding to the failed bank.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes vertical bank redundancy in three-dimensional (3D) stacked dynamic random-access memory (DRAM) for improved yield, in accordance with aspects of the present disclosure.

FIG. 2 is a block diagram illustrating a high-bandwidth three-dimensional (3D) stacked memory chip configured with vertical bank redundancy for improved memory yield, according to various aspects of the present disclosure.

FIG. 3 illustrates a layout view of the stack of memory dies of the high-bandwidth three-dimensional (3D) stacked memory chip of FIG. 2, in which vertical bank redundancy is utilized for improved yield, according to various aspects of the present disclosure.

FIGS. 4A and 4B further illustrate the vertical bank redundancy of the high-bandwidth three-dimensional (3D) stacked memory chip shown in FIGS. 2 and 3, according to various aspects of the present disclosure.

FIG. 5 illustrates a layout view of the high-bandwidth three-dimensional (3D) stacked memory chip shown in FIGS. 2, 3, and 4A-4B to illustrate an energy/bit assessment, according to various aspects of the present disclosure.

FIG. 6 is a process flow diagram illustrating a method for forming vertical bank redundancy in three-dimensional (3D) stacked dynamic random-access memory (DRAM) for improved yield, according to various aspects of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of a semiconductor component, such as the vertical bank redundancy in three-dimensional (3D) stacked dynamic random-access memory (DRAM) for improved yield disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to.” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a higher-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D)-stacked memories composed of high-bandwidth memory (HBM) DRAM provide advantages in performance and power for memory-demanding workloads. Single stacked DRAM yield is a significant factor in these 3D stacked memories. For example, a single DRAM yield of 97% is reduced to a stacked yield of less than 78% in an integration scheme that utilizes low-cost wafer-to-wafer stacking of eight wafers. Due to this limited yield, DRAM vendors prefer slow and costly die-to-die stacking for implementing HBM solutions. Additionally, conventional repair techniques (e.g., redundant row, column, and error correction code (ECC)) fail to increase the single DRAM wafer yield to a desired level.

In conventional implementations, each DRAM die in a stack of, for example, four DRAM dies, is configured with four (4) channels having dedicated input/outputs (IOs). The channels of the vertical DRAM dies are arranged side-by-side on a base die. Unfortunately, signal routing to IOs and potential memory controllers on the physical IO module (PHY) involves long wirelengths resulting in a performance and energy/bit penalty. Additionally, significant difficulty is incurred when employing IO and/or bank multiplexing on the base die for performing repairs of a failing bank and/or IO. In particular, the base die is unavailable for performing repairs using, for example, a repair circuit. While redundant data (DQs) connected to redundant banks may be utilized to perform repairs, a significantly lengthy lateral routing from the redundant IO to the failing IO incurs an area and energy penalty. Consequently, utilizing bank-level redundancy in 3D stacked memories is not practical due to a large area penalty because bank-level redundancy specifies redundant bank columns in each channel.

Various aspects of the present disclosure are directed to vertical bank redundancy in three-dimensional (3D) stacked dynamic random-access memory (DRAM) for improved yield. Various aspects of the present disclosure are directed to a novel bank architecture that allows both row-block redundancy within both a bank tile and across 3D vertical stacks. In various aspects of the present disclosure, a new physical design architecture supports improved organization of package input-outputs (IOs) resulting in a significant energy/bit signaling reduction. Additionally, the proposed bank architecture does not limit the noteworthy features of DRAM (e.g., channel, bandwidth, random access scheme through multi-banks/channel, lost bank access) under the presence of defects. Implementation of the bank architecture involves a simple capacity increase (+5%) for enabling close to 100% yield at the target capacity.

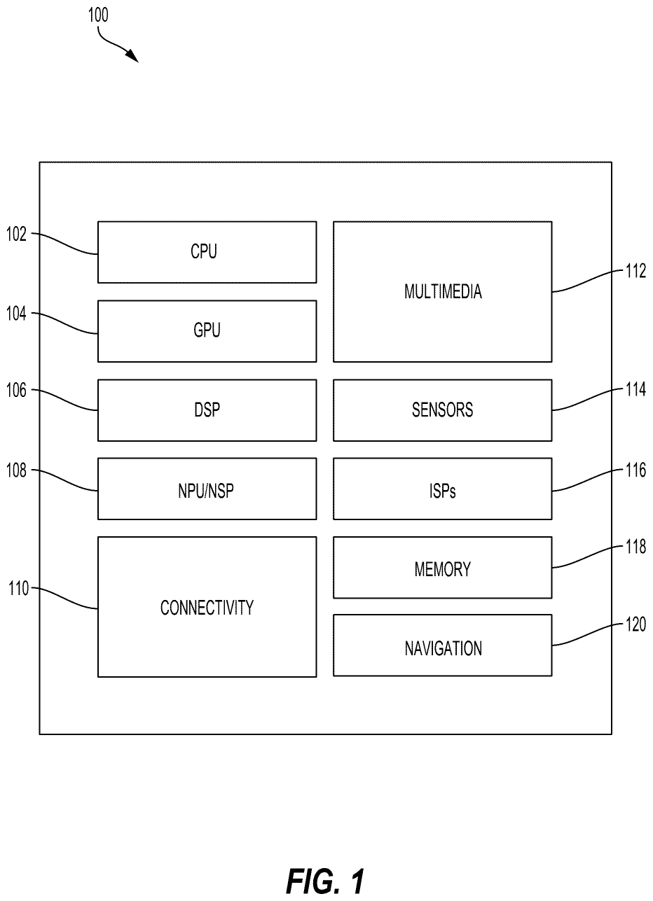

FIG. 1 illustrates an example implementation of a host system-on-chip (SoC) 100, which includes vertical bank redundancy in three-dimensional (3D) stacked dynamic random-access memory (DRAM) for improved yield, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

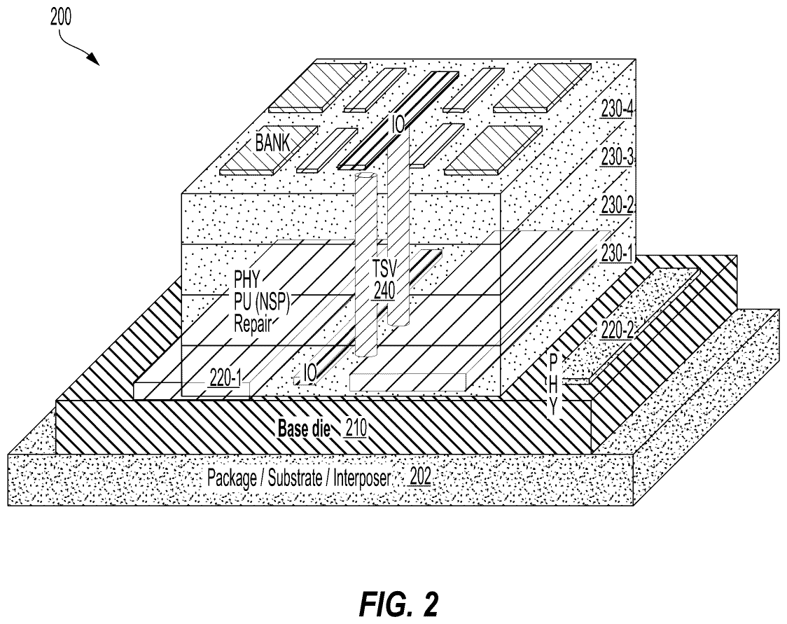

FIG. 2 is a block diagram illustrating a high-bandwidth three-dimensional (3D) stacked memory chip 200 configured with vertical bank redundancy for improved memory yield, according to various aspects of the present disclosure. As shown in FIG. 2, the high-bandwidth 3D stacked memory chip 200 includes a base die 210 (e.g., a first die) that is supported by a package substrate 202 (e.g., interposer). In various aspects of the present disclosure, the base die 210 supports stacking of memory dies 230 (e.g., dynamic random-access memory (DRAM) dies) on the base die 210. The number of memory dies stacked on the base die 210 varies in different implementations. In this example, four (4) memory dies 230 (230-1, 230-2, 230-3, 230-4) are arranged using a back-to-face stacking of DRAM dies on the base die 210. In another implementation, the base die 210 supports a stack of twelve (12) DRAM dies.

In various aspects of the present disclosure, the memory dies 230 include memory banks (BANK) and an input/output (IO) block that utilize signal through silicon vias (TSVs) 240 extending through the memory dies 230 (e.g., second die) and landing on the base die 210. As shown in FIG. 2, the signal TSVs 240 provide signal transmission between the memory dies 230 and a physical IO module (PHY) 220 of the base die 210. In this example, a processing unit (PU) (e.g., a neural signal processor (NSP)) may be implemented on the base die 210 in combination with a first PHY 220-1, including a second PHY 220-2 to a system-on-chip (e.g., SoC 100). Additionally, the high-bandwidth 3D stacked memory chip 200 includes DRAM power TSVs (not shown) between the memory banks and the package substrate 202. FIG. 2 illustrates two (2) TSVs 240 to avoid obscuring the view of the drawing; however, one of skill in the art can readily recognize that there can be more TSVs in the stack of memory dies 230 and/or TSVs at other locations within the stack of memory dies 230.

In conventional implementations, each of the memory dies 230 in the stack of, for example, four DRAM dies, is configured with four (4) channels having dedicated input/outputs (IOs). The channels of the vertical DRAM dies are arranged side-by-side on the base die 210. Unfortunately, signal routing to IOs and potential memory controllers on the PHY 220 involves long wirelengths resulting in a performance and energy/bit penalty. Additionally, significant difficulty is incurred when employing IO and/or bank multiplexing on the base die 210 for performing repairs of a failing bank and/or IO. In particular, the base die 210 is unavailable for performing repairs using, for example, a repair circuit.

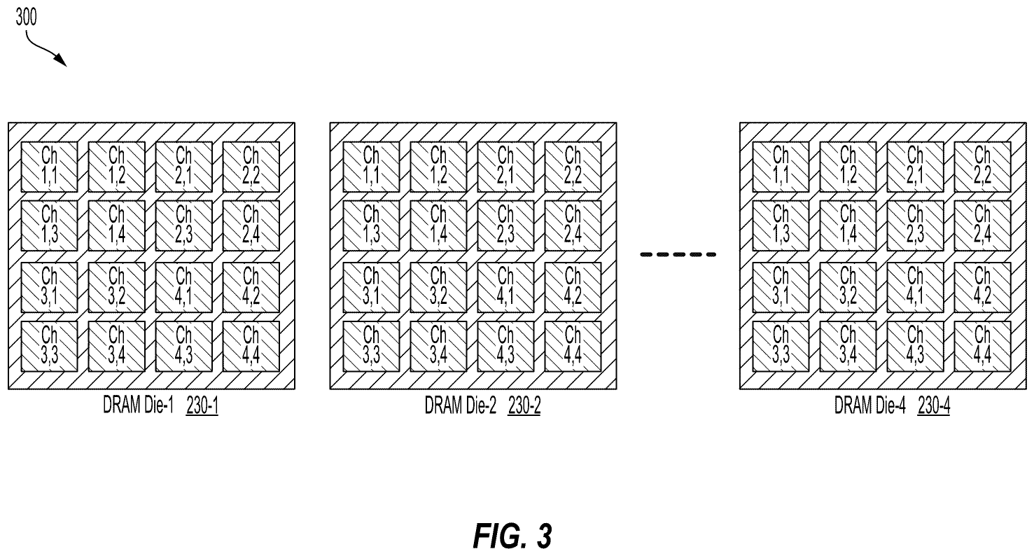

While redundant data (DQs) connected to redundant banks may be utilized to perform repairs, a significantly lengthy lateral routing from the redundant IO to the failing IO incurs an area and energy penalty. Also, many conventional memory dies are limited to the redundancy resided within the same memory die. In other words, a memory die within a stack of memory dies, which has already exhausted its own redundancy, cannot leverage the redundancy available in another memory die within the same stack to make further repairs. A bank-level redundancy in the high-bandwidth 3D stacked memory chip 200 is further illustrated, for example, in FIG. 3.

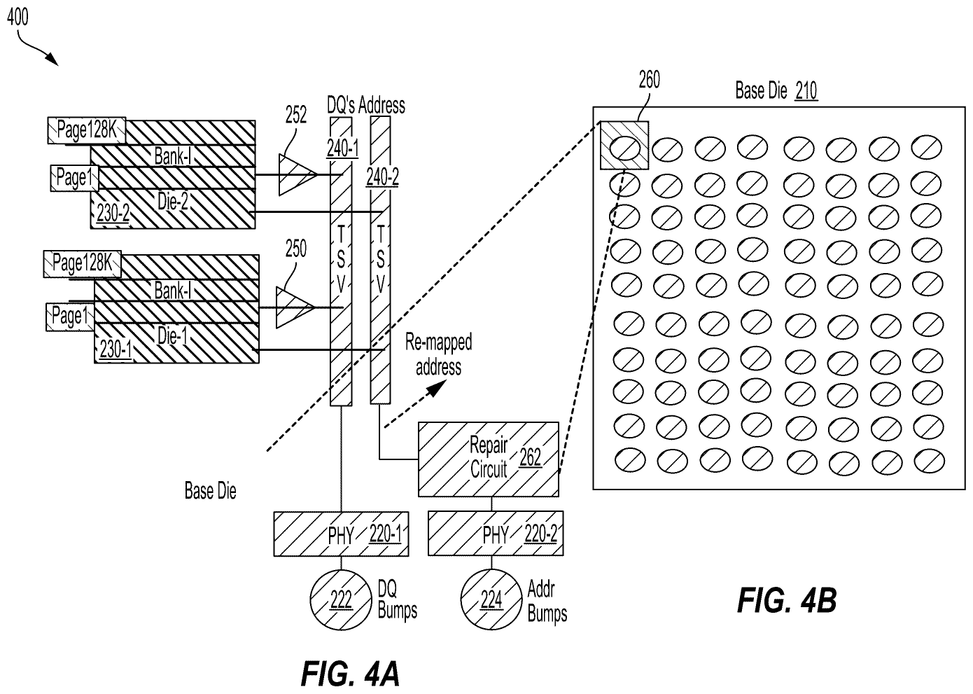

FIG. 3 illustrates a layout view 300 of the stack of memory dies 230 (230-1, 230-2, . . . 230-4) of the high-bandwidth three-dimensional (3D) stacked memory chip 200 of FIG. 2, in which vertical bank redundancy is utilized for improved yield, according to various aspects of the present disclosure. FIG. 3 illustrates a novel bank architecture that allows both row-block redundancy within both a bank tile and across 3D vertical stacks of the memory dies 230. In this example, a first memory die 230-1 includes sixteen channels (e.g., Ch 1,1, . . . . Ch 1,4, Ch 2,1, . . . . Ch 2,4, Ch 3,1, . . . .Ch 3,4, and Ch 4,1, . . . . Ch 4,4). Similarly, a second memory die 230-2 repeats the same sixteen channels (e.g., Ch 1,1, . . . . Ch 1,4, Ch 2,1, . . . . Ch 2,4, Ch 3,1, . . . . Ch 3,4, and Ch 4,1, . . . . Ch 4,4). Additionally, a third memory die 230-3 (not shown) and a fourth memory die 230-4 repeat the same sixteen channels (e.g., Ch 1,1, . . . . Ch 1,4, Ch 2,1, . . . .Ch 2,4, Ch 3,1, . . . . Ch 3,4, and Ch 4,1, . . . . Ch 4,4). According to various aspects of the present disclosure, repeating the same sixteen channels across the 3D vertical stacks of the memory dies 230 provides both row-block redundancy within both a bank tile and across the stack of memory dies 230, as further illustrated in FIGS. 4A and 4B.

FIGS. 4A and 4B further illustrate the vertical bank redundancy of the high-bandwidth three-dimensional (3D) stacked memory chip 200 shown in FIGS. 2 and 3, according to various aspects of the present disclosure. FIG. 4A further illustrates a physical IO module (PHY) 220 and micro-bump location 260 from a layout view 400 of the base die 210, as shown in FIG. 4B. As further illustrated in FIG. 4A, the PHY 220 and the micro-bump location 260 include a first PHY 220-1 coupled to data (DQ) bumps 222, and a second PHY 220-2 coupled to address bumps 224, which are coupled to a repair circuit 262. According to various aspects of the present disclosure, the first PHY 220-1 is coupled to a DQ TSV 240-1 and the repair circuit 262 is coupled to an address TSV 240-2. Although a single DQ TSV 240-1 and a single address TSV 240-2 are shown, it should be recognized that multiple sets of data TSVs 240-1 and address TSVs 240-2 are contemplated according to various aspects of the present disclosure.

As shown in FIG. 4A, the DQ TSV 240-1 is coupled to data lines (e.g., DQ lines) of a first memory die 230-1 through a first tri-state switch 250 and coupled to data lines (e.g., DQ lines) of a second memory die 230-2 through a second tri-state switch 252. Similarly, the address TSV 240-2 is coupled to address lines of the first memory die 230-1 and address lines of the second memory die 230-2. In this example, a memory page (Page1) is shown in Bank-1 of the first memory die 230-1 and Bank-1 of the second memory die 230-2, according to the novel bank architecture, for example, as shown in FIG. 3. As shown in FIG. 4A, the novel bank architecture allows both row-block redundancy within both a bank tile and the memory dies 230. In this example, a bank size of 128K bits is shown. Other implementations can have a different bank size.

According to the disclosed bank redundancy, a failing bank (e.g., Bank-1 in the first memory die 230-1) is replaced by a redundant bank at another stacked memory die corresponding to the failed bank, such as the redundant Bank-1 in the second memory die 230-2 using the second tri-state switch 252. According to various aspects of the present disclosure, the repair circuit 262 provides a re-mapped address corresponding to the redundant Bank-1 in the second memory die 230-2 to provide the redundant Bank-1 in the second memory die 230-2 using the second tri-state switch 252. Additionally, the disclosed bank redundancy covers unrepairable areas on a bank (e.g., Bank-1 in the first memory die 230-1) by choosing another bank-tile on another stacked memory die (e.g., Bank-1 in the second memory die 230-2) through the tri-state switches (e.g., 250/252). This technique expands the overall coverage of the redundancy in the stack of memory dies, which tremendously enhances yield of the 3D stacked memory chip as further explained below.

The disclosed bank redundancy results in an improved yield. If a failing page is detected, the failing page is replaced by another page in the same bank in the same memory die. The disclosed bank redundancy further eliminates data (e.g., bandwidth) loss if a bank is lost because banks are formed vertically, such that a lost bank simply incurs a small capacity loss (e.g., ˜<5%). Furthermore, an area penalty associated with the page redundancy is limited (e.g., ˜2%) relative to an alternative bank redundancy area penalty (e.g., ˜15%)

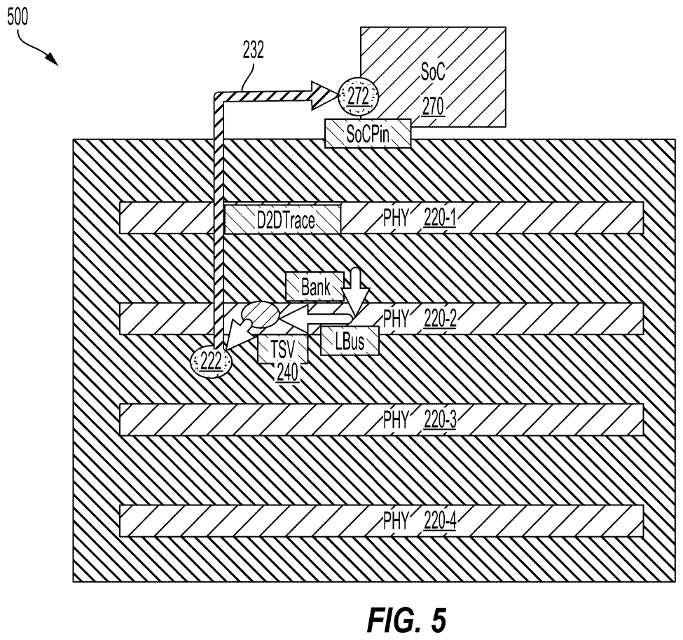

FIG. 5 illustrates a layout view 500 of the high-bandwidth three-dimensional (3D) stacked memory chip 200 shown in FIGS. 2, 3, and 4A-4B to illustrate an energy/bit assessment, according to various aspects of the present disclosure. As shown in FIG. 5, there are four (4) PHY 220 (220-1, 220-2, 220-3, and 220-4) to provide vertical PHY redundancy, in which a bank replacement is performed at the second PHY-220-2. The replacement bank traverses a local bus (LBus) to the TSV 240 to the DQ bumps 222 (e.g., DQ pin) of the base die 210 and is transmitted to a system-on-chip (SoC) pin 272 of an SoC 270 using a die-to-die (D2D) trace 232.

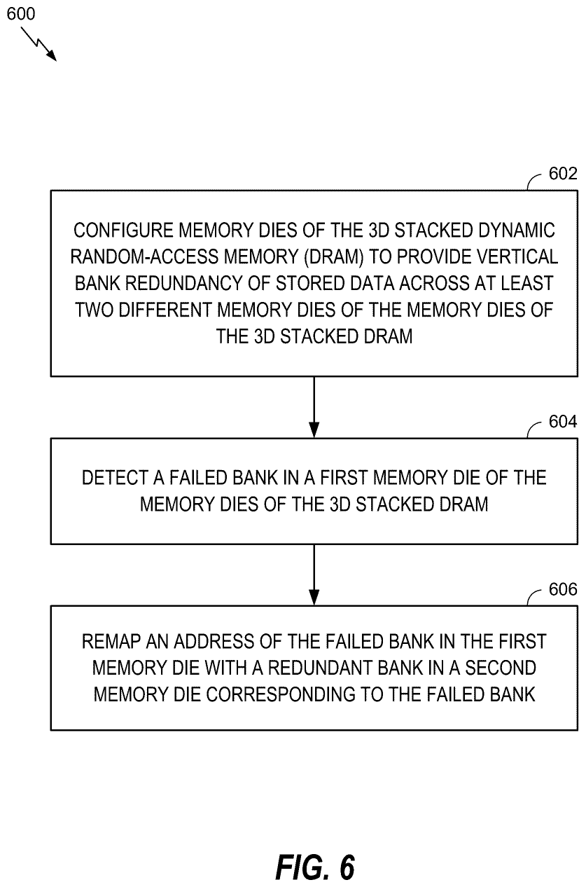

As shown in FIG. 5, the physical design architecture supports improved organization of package input-outputs (IOs) resulting in a significant energy/bit signaling reduction. Additionally, the proposed bank architecture does not limit the noteworthy features of dynamic random-access memory (DRAM) (e.g., channel, bandwidth, random access scheme through multi-banks/channels, and lost bank access) under the presence of defects. Implementation of the bank architecture involves a simple capacity increase (+5%) for enabling close to 100% yield at the target capacity. A process of forming a vertical bank redundancy in 3D stacked DRAM for improved yield is illustrated, for example, in FIG. 6.

FIG. 6 is a process flow diagram illustrating a method 600 for vertical bank redundancy in three-dimensional (3D) stacked dynamic random-access memory (DRAM) for improved yield, according to various aspects of the present disclosure. The method 600 begins at block 602, in which memory dies of the 3D stacked DRAM are configured to provide vertical bank redundancy of stored data across at least two different memory dies of the memory dies of the 3D stacked DRAM. For example, as shown in FIG. 3, the first memory die 230-1 includes sixteen channels (e.g., Ch 1,1, . . . .Ch 1,4, Ch 2,1, . . . . Ch 2,4, Ch 3,1, . . . . Ch 3,4, and Ch 4,1, . . . . Ch 4,4). Similarly, the second memory die 230-2 repeats the same sixteen channels (e.g., Ch 1,1, . . . . Ch 1,4, Ch 2,1, . . . . Ch 2,4, Ch 3,1, . . . . Ch 3,4, and Ch 4,1, . . . . Ch 4,4). Additionally, the third memory die 230-3 (not shown) and a fourth memory die 230-4 repeat the same sixteen channels (e.g., Ch 1,1, . . . . Ch 1,4, Ch 2,1, . . . . Ch 2,4, Ch 3,1, . . . . Ch 3,4, and Ch 4,1, . . . Ch 4,4). As shown in FIG. 3, repeating the same sixteen channels across the 3D vertical stacks of the memory dies 230 provides both row-block redundancy within both a bank tile and across the stack of memory dies 230.

At block 604, a failed bank is detected in a first memory die of the memory dies of the 3D stacked DRAM. At block 606, an address of the failed bank in the first memory die is remapped with a redundant bank in a second memory die corresponding to the failed bank. For example, as shown in FIG. 4A, a failing bank (e.g., Bank-1 in the first memory die 230-1) is replaced by a redundant bank at another stacked memory die corresponding to the failed bank, such as the redundant Bank-1 in the second memory die 230-2. According to various aspects of the present disclosure, the repair circuit 262 provides a re-mapped address corresponding to the redundant Bank-1 in the second memory die 230-2.

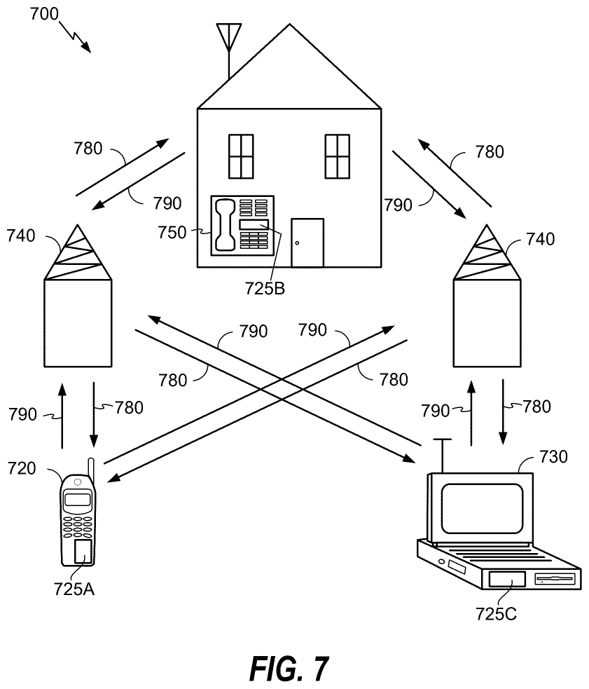

FIG. 7 is a block diagram showing an exemplary wireless communications system 700 in which a configuration of the disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include integrated circuit (IC) devices 725A, 725C, and 725B that include the disclosed vertical bank redundancy in 3D stacked dynamic random-access memory (DRAM) for improved yield. It will be recognized that other devices may also include the disclosed vertical bank redundancy in 3D stacked DRAM for improved yield, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to aspects of the present disclosure, the disclosure is not limited to these exemplary illustrated units. Aspects of the present disclosure may be suitably employed in many devices, which include the disclosed vertical bank redundancy in 3D stacked DRAM for improved yield.

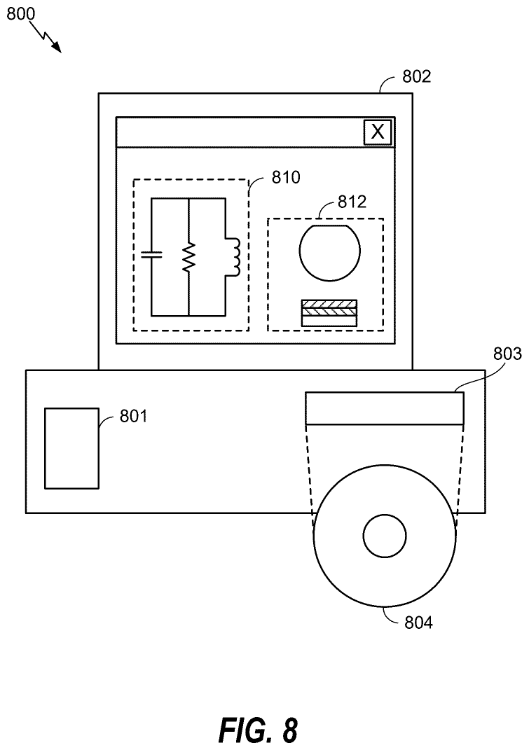

FIG. 8 is a block diagram illustrating a design workstation used for circuit, layout, and logic design of a semiconductor component, such as the vertical bank redundancy in three-dimensional (3D) stacked dynamic random-access memory (DRAM) for improved yield disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812, such as vertical bank redundancy in 3D stacked DRAM for improved yield. A storage medium 804 is provided for tangibly storing the design of the circuit 810 or the IC component 812 (e.g., the DRAM/SRAM SoC integration). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

Implementation examples are described in the following numbered clauses:
1. A three-dimensional (3D) stacked memory package, comprising:
a base die, including a repair circuit;
a plurality of memory dies stacked on the base die;
a package substrate supporting the base die; and
data through silicon vias (TSVs) extending between the plurality of memory dies and landing on the base die, in which the data TSVs are shared on data (DQ) lines for each of the plurality of memory dies, in which the repair circuit is configured to remap addresses of failed banks and/or pages across at least two different memory dies of the plurality of memory dies.
2. The 3D stacked memory package of clause 1, in which the repair circuit is further configured to remap an address of a failed bank in a first memory die with a redundant bank in a second memory die corresponding to the failed bank.
3. The 3D stacked memory package of clause 1, in which the repair circuit is further configured to remap an address of a failing page in a first memory die with another page in the first memory die.
4. The 3D stacked memory package of any of clauses 1-3, further comprising through tri-state switches coupling the data TSVs to the DQ lines for each of the plurality of memory dies.
5. The 3D stacked memory package of any of clauses 1-4, further comprising a physical IO module (PHY) coupled to the data TSVs.
6. The 3D stacked memory package of clause 5, further comprising DQ bumps coupled to the data TSVs through the PHY.
7. The 3D stacked memory package of any of clauses 1-6, further comprising address TSVs extending between the plurality of memory dies and landing on the base die.
8. The 3D stacked memory package of clause 7, in which the repair circuit is coupled to the address TSVs.
9. The 3D stacked memory package of clause 7, further comprising a physical IO module (PHY) coupled to the address TSVs.
10. The 3D stacked memory package of clause 9, further comprising address bumps coupled to the address TSVs through the PHY.
11. A method for three-dimensional (3D) stacked dynamic random-access memory (DRAM) repair, the method comprising:
configuring a plurality of memory dies of the 3D stacked DRAM to provide vertical bank redundancy of stored data across at least two different memory dies of the plurality of memory dies of the 3D stacked DRAM;
detecting a failed bank in a first memory die of the plurality of memory dies of the 3D stacked DRAM; and
remapping an address of the failed bank in the first memory die with a redundant bank in a second memory die corresponding to the failed bank.
12. The method of clause 11, further comprising remapping an address of a failed bank in the first memory die with the redundant bank in the second memory die corresponding to the failed bank.
13. The method of clause 11, further comprising remapping an address of a failing page in the first memory die with another page in the first memory die.
14. The method of any of clauses 11-13, further comprising forming through tri-state switches coupling data through silicon vias (TSVs) to data (DQ) lines for each of the plurality of memory dies.
15. The method of clause 14, further comprising forming a physical IO module (PHY) coupled to the data TSVs.
16. The method of clause 15, further comprising forming DQ bumps coupled to the data TSVs through the PHY.
17. The method of any of clauses 11-16, further comprising forming address TSVs extending between the plurality of memory dies and landing on a base die.
18. The method of clause 17, in which a repair circuit is coupled to the address TSVs.
19. The method of clause 17, further comprising forming a physical IO module (PHY) coupled to the address TSVs.
20. The method of clause 19, further comprising forming address bumps coupled to the address TSVs through the PHY.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A three-dimensional (3D) stacked memory package, comprising:
a base die, including a repair circuit;
a plurality of memory dies stacked on the base die;
a package substrate supporting the base die; and
data through silicon vias (TSVs) extending between the plurality of memory dies and landing on the base die, in which the data TSVs are shared on data (DQ) lines for each of the plurality of memory dies, in which the repair circuit is configured to remap addresses of failed banks and/or pages across at least two different memory dies of the plurality of memory dies.

2. The 3D stacked memory package of claim 1, in which the repair circuit is further configured to remap an address of a failed bank in a first memory die with a redundant bank in a second memory die corresponding to the failed bank.

3. The 3D stacked memory package of claim 1, in which the repair circuit is further configured to remap an address of a failing page in a first memory die with another page in the first memory die.

4. The 3D stacked memory package of claim 1, further comprising through tri-state switches coupling the data TSVs to the DQ lines for each of the plurality of memory dies.

5. The 3D stacked memory package of claim 1, further comprising a physical IO module (PHY) coupled to the data TSVs.

6. The 3D stacked memory package of claim 5, further comprising DQ bumps coupled to the data TSVs through the PHY.

7. The 3D stacked memory package of claim 1, further comprising address TSVs extending between the plurality of memory dies and landing on the base die.

8. The 3D stacked memory package of claim 7, in which the repair circuit is coupled to the address TSVs.

9. The 3D stacked memory package of claim 7, further comprising a physical IO module (PHY) coupled to the address TSVs.

10. The 3D stacked memory package of claim 9, further comprising address bumps coupled to the address TSVs through the PHY.

11. A method for three-dimensional (3D) stacked dynamic random-access memory (DRAM) repair, the method comprising:
configuring a plurality of memory dies of the 3D stacked DRAM to provide vertical bank redundancy of stored data across at least two different memory dies of the plurality of memory dies of the 3D stacked DRAM;
detecting a failed bank in a first memory die of the plurality of memory dies of the 3D stacked DRAM; and
remapping an address of the failed bank in the first memory die with a redundant bank in a second memory die corresponding to the failed bank.

12. The method of claim 11, further comprising remapping an address of a failed bank in the first memory die with the redundant bank in the second memory die corresponding to the failed bank.

13. The method of claim 11, further comprising remapping an address of a failing page in the first memory die with another page in the first memory die.

14. The method of claim 11, further comprising forming through tri-state switches coupling data through silicon vias (TSVs) to data (DQ) lines for each of the plurality of memory dies.

15. The method of claim 14, further comprising forming a physical IO module (PHY) coupled to the data TSVs.

16. The method of claim 15, further comprising forming DQ bumps coupled to the data TSVs through the PHY.

17. The method of claim 11, further comprising forming address TSVs extending between the plurality of memory dies and landing on a base die.

18. The method of claim 17, in which a repair circuit is coupled to the address TSVs.

19. The method of claim 17, further comprising forming a physical IO module (PHY) coupled to the address TSVs.

20. The method of claim 19, further comprising forming address bumps coupled to the address TSVs through the PHY.
